(19) United States
(12) Patent Application Publication
(10) Pub. No.: US 2008/0205009 A1
(43) Pub. Date: Aug. 28, 2008

(54) Electronic apparatus and mounting method

(75) Inventor: Yoshinobu Maeno, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki-shi (JP)

(21) Appl. No.: 12/003,671

(22) Filed: Dec. 28, 2007

(30) Foreign Application Priority Data
Feb. 28, 2007 (JP) 2007-050773

(51) Int. Cl. H05K 7/02; H05K 3/30

(52) U.S. Cl. 361/760; 29/832

(57) ABSTRACT

An electronic apparatus includes: a package body that has a tabular outside shape and is packaged with a built-in electronic circuit; a bump that electrically connects the electronic circuit inside the package body to a wiring outside the package body; a wiring board that has a wiring at least on its surface, the wiring board mounted with the package body so that the electronic circuit of the package body is electrically connected to the wiring via the bump; and an adhesive that bonds the package body onto the wiring board so as to bond only an edge of the package body to the wiring board.

### BACKGROUND OF THE INVENTION

1. Field of the Invention

The present invention relates to electronic apparatus in which a package body packaged with a built-in electronic circuit is mounted on a wiring board, and a mounting method by which the package body is mounted on the wiring board.

2. Description of the Related Art

Recently, mobile devices represented by a mobile phone and a notebook type personal computer or the like have become widespread. And there is the constant demand for a more compact mobile device in the market. In response to such a demand, miniaturization of electronic apparatus of various kinds has been realized, such as a circuit board embedded in a mobile device.

Here, as one effective method for realizing miniaturization of electronic apparatus, it has become a focus of attention to use small sized electronic parts, for example, such as Ball Grid Array (BGA) and Chip Scale Package (CSP), which are recently rapidly advancing in the field of electronic parts of electronic apparatus, such as an IC package. The BGA uses a minute solder ball (bump) or the like instead of a pin terminal used in conventional electronic parts, for example, in Quad Flatpack Package (QFP) and others, for connecting a circuit chip built inside a package body to a wiring outside the package body. The BGA has achieved more miniaturization compared to the QFP through its grid shape array of bumps arranged on the surface of the package body, etc. Moreover, the CSP has achieved further miniaturization by narrowing array pitch of bumps of the BGA. Additionally, inside the package body of the BGA and the CSP, a circuit chip is connected to an intermediate board that connects the circuit chip and each of the bumps together, and a technique is proposed which uses bumps also for connecting the circuit chip, instead of conventional so-called wire bonding (for example, see Japanese Patent Application Publication Nos. 2000-164635, 2002-16195 and 2000-260790). Recently, the BGA and the CSP are becoming more compact through the use of bumps for connecting a circuit chip within a package body.

By the way, in the electronic apparatus in which electronic parts such as these BGA and CSP are mounted on a wiring board, a package body of the electronic part and the wiring board are connected to each other in a very short distance compared to conventional QFP and so on. Here, between the package body and the wiring board, stress is generated repeatedly, for example, due to external force applied to this kind of electronic apparatus or due to the difference of a thermal expansion coefficient between the package body and the wiring board. The stress generated between the package body and the wiring board is likely to concentrate in a portion having insufficient strength such as a portion connecting the package body to the bump or a portion connecting the bump to the wiring board, which leads to a problem that cracking occurs in such portions.

To avoid such problems, at the time of mounting the BGA and the CSP or the like on a wiring board, an adhesive called under-fill is made to fill in the space between the package body of the electronic part and the wiring board so that the stress generated between the package body and the wiring board can be dispersed.

Here, it often happens that a so-called repair processing becomes necessary, which replaces an electronic part in a mounted state with a new one, for example, due to a failure detected in the electronic part after it has been placed or the like. However, if the placement has been done with the use of under-fill as described above, the repair processing accompanies a lot of labor and difficulties and puts a heavy burden on a worker.

### SUMMARY OF THE INVENTION

The present invention has been made in view of the above circumstances and provides electronic apparatus capable of executing a repair processing easily for an electronic part in a state of being mounted and a mounting method that enables mounting such that the repair processing of the electronic part becomes easier after it has been mounted.

The electronic apparatus according to the present invention includes: a package body that has a tabular outside shape and is packaged with a built-in electronic circuit; a bump that electrically connects the electronic circuit inside the package body to a wiring outside the package body; a wiring board that has a wiring at least on its surface, the wiring board mounted with the package body so that the electronic circuit of the package body is electrically connected to the wiring via the bump; and an adhesive that bonds the package body onto the wiring board so as to bond only an edge of the package body to the wiring board.

Conventionally, in the electronic apparatus in which an electronic part like the above is placed on a wiring board with the use of under-fill, the space between the package body of the electronic part and the wiring board is filled with the under-fill due to the capillary phenomenon or the like. Previously, it has been considered that, by making the under-fill to fill in the gap between the package body and the wiring board, the package body is adhered as a whole to the wiring board, and as a result, the stress generated between the package body and the wiring board can be well dispersed. In contrast, the inventor of the present invention has found that, similar effect can be obtained for the dispersion of this stress, by bonding only the edge of the package body to the wiring board without bonding the entire package body of the electronic part to the wiring board. The present invention has been made based on this finding. In the electronic apparatus according to the present invention, only the edge of the package body is bonded to the wiring board. As described above, with this bonding limited to the edge, it is possible to secure effect of dispersing the stress generated between the package body and the wiring board. Furthermore, by such bonding limited to the edge, the repair processing of the electronic apparatus in the mounted state becomes by far easier compared to a case in which the package body of the electronic apparatus has been entirely bonded to the wiring board. That is, according to the electronic apparatus of the present invention, the repair processing can be executed easily for an electronic part in the mounted state.

Here, in the electronic apparatus according to the present invention, it is preferable that the adhesive bonds the edge of the package body on the wiring board excepting a portion of the entire perimeter of the edge.

According to this preferable feature, for example, in such a case where a thermosetting type adhesive is used as the adhesive and even if the air accumulated in the space between the package body and the wiring board expands at the time of heating, the portion described above functions as an escape route of the expanded air. This makes it possible not to exert unwanted pressure on the adhesive to be hardened yet and thereby to avoid faulty bonding or the like due to the peeling of the adhesive. Moreover, this portion also becomes an escape route of the air that expands through the heat emitted by the electronic circuit during its operation.

Further, in the electronic apparatus according to the present invention, it is preferable as well that the package body has a rectangular outside shape, and that the adhesive adheres at least corners of the rectangular outside shape of the edge of the package body, onto the wiring board.

According to this preferable feature, bonding is executed at the corners that are especially effective in dispersing the stress generated between the package body of the electronic part and the wiring board, so that dispersion of the stress as well as convenience in repair processing can be ensured.

Moreover, in the electronic apparatus according to the present invention, it is also preferable that the adhesive widens from the package body toward the wiring board, and that the adhesive has a slant surface with a slant angle of not less than 30-degree and less than 60-degree with respect to the wiring board.

According to this preferable feature, the adhesive is in such a shape that is suitable for dispersion of the stress, and thus it is possible to obtain enhanced adhesive strength.

Also in the electronic apparatus of the present invention, it is also preferable that the adhesive has a viscosity of not less than 50 Pa·s before hardening.

According to this preferable feature, since the adhesive has enough viscosity to prevent it from entering a gap between the package body and the wiring board due to the capillary phenomenon or the like, it is possible to avoid a case in which unwanted spread of bonded area makes repair processing difficult.

Furthermore, in the electronic apparatus of the present invention, it is also preferable that the adhesive is kept from contact with the bump.

According to this preferable feature, since the bump and the adhesive are separately bonded to the wiring board, at the time of the repair processing, it is possible to individually remove remains of the bump and the adhesive on the wiring board.

Furthermore, a mounting method according to the present invention includes the steps of: electrically connecting an electronic circuit embedded and packaged inside a package body to a wiring of a wiring board via a bump that electrically connects the electronic circuit to a wiring outside the package body, the package body having a tabular outside shape, the wiring being laid at least on a surface of the wiring board; and bonding the package body onto the wiring board so as to bond only an edge of the package body to the wiring board.

According to this preferable mounting method, since bonding is executed by limiting it to the edge of the package body of the electronic part, the repair processing of the electronic part after the mounting becomes easy. That is, according to the mounting method of the present invention, it is possible to mount the electronic part in such a manner that makes the repair processing easier after it has been mounted.

Also in the mounting method according to the present invention, it is preferable that the step of bonding is a step of bonding the edge of the package body to the wiring board excepting a portion of the perimeter of the edge.

Further, in the mounting method according to the present invention, it is preferable that the package body has a rectangular outside shape, and the step of bonding is a step of bonding at least corners of the rectangular outside shape of the edge of the package body, to the wiring board.

Moreover, in the mounting method according to the present invention, it is preferable that the step of bonding is a step that executes the bonding with the use of an adhesive, and further, that spreads the adhesive from the package body toward the wiring board. Also it is preferable that the step of bonding is a step that executes the bonding with the use of an adhesive, and further, that spreads the adhesive from the package body to the wiring board so that the adhesive has a slant surface with a slant angle of not less than 30-degree and less than 60-degree with respect to the wiring board.

In addition, in the mounting method according to the present invention, it is preferable as well that the step of bonding is a step that executes the bonding with the use of an adhesive having the viscosity of not less than 50 Pa·s before hardening.

Additionally, in the mounting method according to the present invention, it is also preferable that the step of bonding is a step that executes the bonding with the use of an adhesive, and further, that executes the bonding in such a way that the adhesive is kept from contact with the bump.

As explained above, according to the present invention, it is possible to obtain an electronic apparatus capable of executing a repair processing easily for an electronic part in the mounted state and a mounting method that enables mounting in such a manner that makes the repair processing of the electronic part easier after it has been mounted.

### BRIEF DESCRIPTION OF THE DRAWINGS

FIG. 1 is a diagram illustrating one embodiment of an electronic apparatus according to the present invention;

FIG. 2 is a schematic diagram illustrating an example of mounting a BGA type electronic part shown in FIG. 1;

FIG. 3 is a diagram illustrating an example of easy repair processing of the BGA type electronic part shown in FIGS. 1 and 2;

FIG. 4 is a diagram illustrating another example of an adhesive; and

FIG. 5 is a flowchart illustrating a mounting method of mounting the BGA type electronic part on the wiring board in another example shown in FIG. 4.

### DETAILED DESCRIPTION OF THE INVENTION

The embodiments of the present invention will be described below with reference to the accompanying drawings.

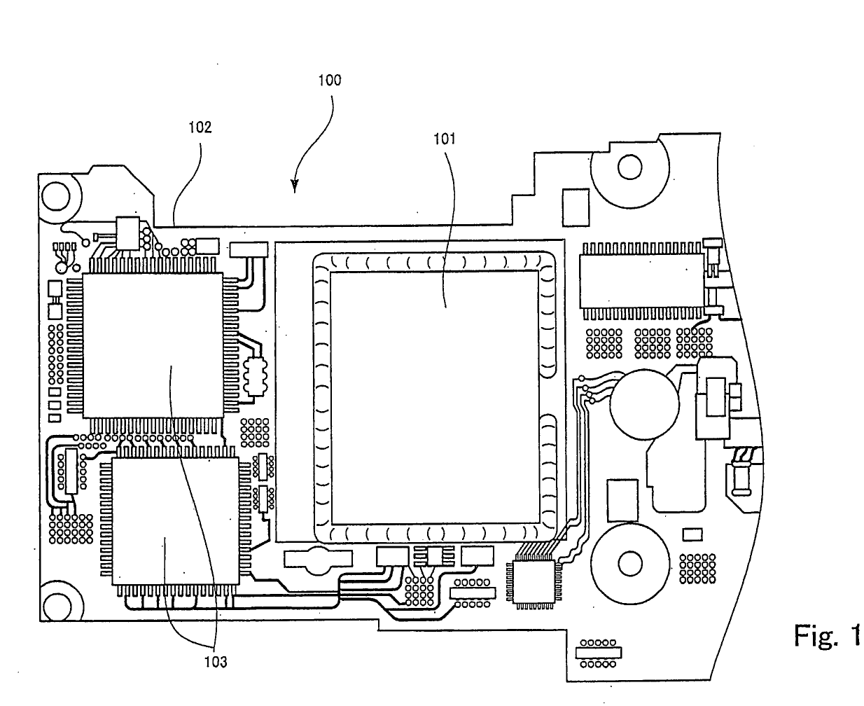

FIG. 1 is a diagram illustrating one embodiment of the electronic apparatus according to the present invention.

This FIG. 1 shows a top view of a circuit board 100 as one embodiment of the electronic apparatus of the present invention. In this circuit board 100, a BGA type electronic part 101 is mounted on a wiring board 102. Additionally, in this circuit board 100, various kinds of parts such as a QFP type electronic part 103 and others are mounted other than the BGA type electronic part 101. Here, since the feature of this circuit board 100 as one embodiment of the present invention relates to the embodiment of mounting the BGA type electronic part 101, hereinafter an explanation will be given about the embodiment of mounting this BGA type electronic part 101.

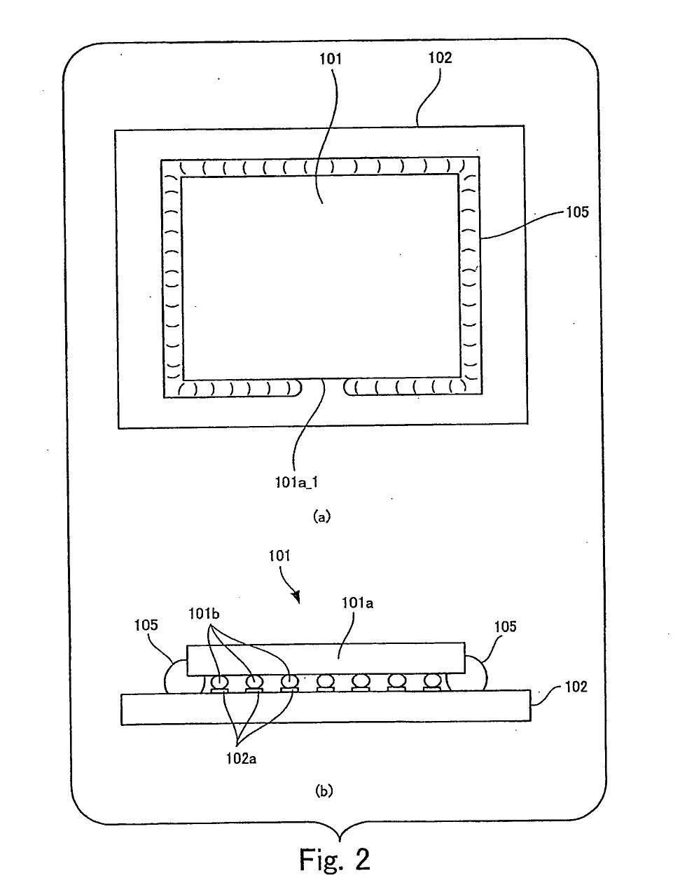

FIG. 2 is a schematic diagram illustrating the mounting embodiment of the BGA type electronic part 101 shown in FIG. 1.

Part (a) of FIG. 2 schematically illustrates the top view of the BGA type electronic part 101 in the state of being mounted on the wiring board 102, and Part (b) of FIG. 2 schematically illustrates a cross-sectional diagram of the BGA type electronic part 101 in this state.

In the present embodiment, the BGA type electronic part 101 includes plural bumps 101b made of solder ball arranged in a grid shape on the backside of a part body 101a that has a tabular outside shape and a built-in circuit chip. The plural bumps 101b are placed on plural land terminals 102a formed on the wiring board 102 such that the bumps 101b respectively corresponds to the land terminals 102a. Then, the bumps placed on the wiring board 102 are melted. Accordingly, the part body 101a is soldered to the wiring board 102 and thereby the circuit chip of the part body 101a is electrically connected to the wiring board 102. Further, the part body 101a of the BGA type electronic part 101 is bonded to the wiring board 102 via an adhesive 105 such that only the edge of the part body 101a is bonded to the wiring board 102. Here, the part body 101a corresponds to an example of the package body in the present invention; the bump 101b corresponds to an example of the bump in the present invention; the wiring board 102 corresponds to an example of the wiring board in the present invention; and the adhesive 105 corresponds to an example of the adhesive in the present invention.

As shown in part (a) of FIG. 2, the adhesive 105 is applied to the edge of the part body 101a excepting one arbitrary portion 101a_1 of the edge of the part body 101a, and a ratio of bonded portion to the entire perimeter (edge) of the part body 101a is 90% or more and less than 100%. It should be noted that the four corners of the part body 101a in a rectangular sheet shape are included in the bonded portion.

Here, on the occasion of the present invention, the inventor of the present invention has conducted an endurance test by using a notebook type personal computer with a built-in wiring board mounted with the BGA type electronic part. In the test, experimental external force has been applied 3000 times to the computer with extra allowance of a predetermined margin for the force to be applied at the time of operation. The endurance test has shown that even in a case where only the edge of the BGA type electronic part is bonded to the wiring board, the same strength can be obtained as the one in a case where the BGA type electronic part is entirely bonded to the wiring board. That is, in the present embodiment, bonding the edge of the part body 101a to the wiring board 102 makes it sufficient to disperse the stress and makes it possible to avoid failures such as cracking at relatively weak portions such as portions where the bumps 101b are attached to the part body 101a, and where the bumps 101b are bonded to the wiring board 102 or the like.

Also in the present embodiment, the adhesive 105 is a thermosetting adhesive and is heated after it is applied to the edge of the part body 101a and the wiring board 102. When the adhesive 105 is heated, the air in the space between the lower portion of the part body 101a and the wiring board 102 expands, but escapes from the portion 101a_1. In this way, unwanted stress is not put on the adhesive 105 that is not cured yet, so that it is possible to avoid bonding failure due to peeling of the adhesive 105. Furthermore, when the circuit chip of the BGA type electronic part 101 is heated during operation, air expanded by the heat transmitted by the circuit chip can also escape from the portion 101a_1.

Moreover, as shown in Part (b) of FIG. 2, the adhesive 105 is applied so as not to make the adhesive 105 come into contact with the bumps 101b.

Also, in the present embodiment, the adhesive 105 has a characteristic of maintaining the viscosity of 50 Pa·s or more until hardening is completed through the application of heat from room temperature to hardening temperature. Because of this, until hardening is completed after the adhesive 105 has been applied to the edge of this part body 101a and the wiring board 102, the adhesive 105 does not enter the gap between the part body 101a of the BGA type electronic part 101 and the wiring board 102 due to a capillary phenomenon or the like. As a result, it is possible to prevent unwanted spread of bonded area into the lower portion of the part body 101a.

In the present embodiment, by mounting the BGA type electronic part 101 on the wiring board 102 in the embodiment described above, it is possible to secure enough strength to bear the stress. At the same time, easy repair processing is guaranteed as will be described in the following.

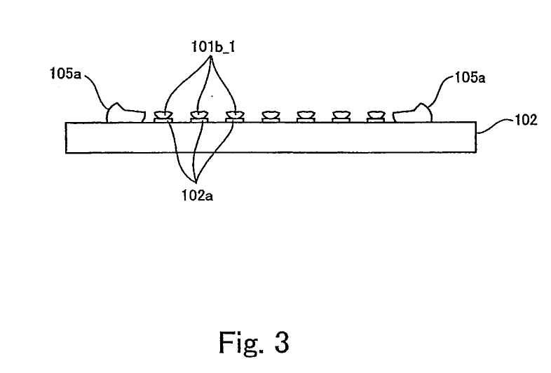

FIG. 3 is a diagram illustrating easy repair processing of the BGA type electronic part 101 shown in FIGS. 1 and 2.

At the repair processing of the BGA type electronic part 101, for example, the BGA type electronic part 101 is first mechanically peeled off from the wiring board 102. In the peeling process, since the bonded portion bonded by the adhesive 105 is limited to the edge of the part body 101a according to the present embodiment, it is easy to peel off the BGA type electronic part 101.

Also, after it has been peeled off, fragments 101b_1 of the bumps 101b and adhesive residues 105a are deposited on the wiring board 102. However, since the adherents on the wiring board 102, that is, the fragments 101b_1 of the bumps 101b and the adhesive residues 105a are separately formed on the wiring board 102 as shown in FIG. 3, the adherents can be disposed of separately and removed easily.

In order to remove the adherents on the wiring board 102, for example, the fragments 101b_1 of the bumps 101b may be melted with the use of a solder iron so as not to damage the land terminals 102a to be absorbed into a solder sucker. At this time, in the present embodiment, since the adhesive residues 105a are not extended to around the land terminals 102a, the fragments 101b_1 of the bumps 101b can be easily removed. At the same time, the repair processing does not require extra load to the land terminals 102a, because the land terminal 102a is subjected to only the load due to the removal of fragments 101b_1 of the bumps 101b.

Further, in order to remove the adhesive residues 105a, they may be wiped after they have been dissolved or swelled by a chemical agent or the like. In the present embodiment, as described above, it is possible to remove the adhesive residues 105a easily, independently of the removal of the fragments 101b_1 of the bumps 101b as well as execute the repair processing without exerting any extra load on the land terminal 102a.

In this way, according to the present embodiment, it is possible to execute the repair processing easily of the BGA type electronic part 101 in the mounted state as well as execute the repair processing without applying any extra load to the land terminals 102a on the wiring board 102.

Incidentally, as an example of the adhesive according to the present invention, the adhesive 105 is applied to the edge of the part body 101a and the wiring board 102. However, the present invention is not limited to this. From now on, another example of the adhesive of the present invention will be described below.

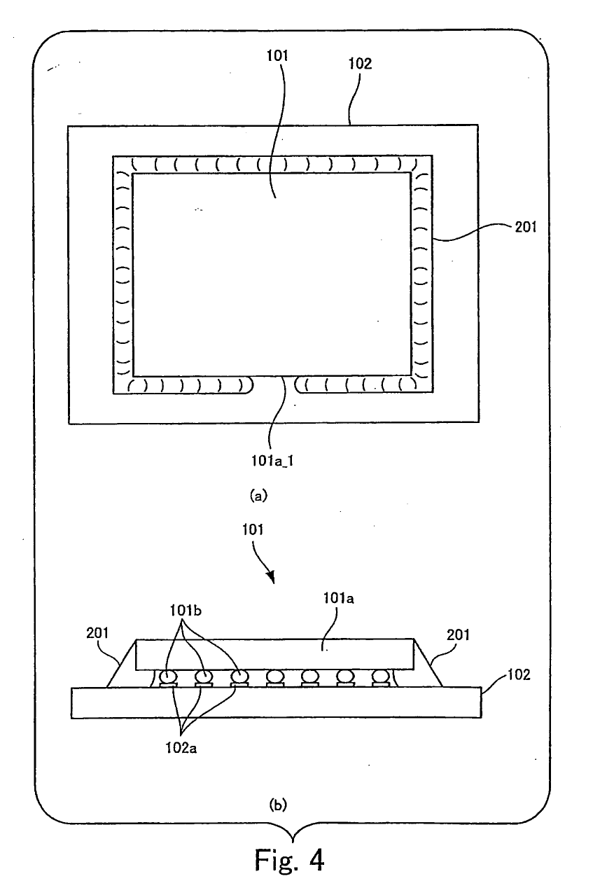

FIG. 4 is a diagram illustrating another example of the adhesive of the present invention.

In this FIG. 4, the same reference characters and numerals as those in FIG. 2 are given to the same component elements as those shown in FIG. 2 to omit redundancy.

Hereinafter, an explanation will be given by paying attention to the embodiment of an adhesive 201 in FIG. 4.

The adhesive 201 in this FIG. 4 is spread from the edge of the top face of the part body 101a to the wiring board 102 (i.e., the top face is opposite to a face of the part body 101a directed to the wiring board 102). And the surface of the adhesive 201 is shaped such that the surface has a slant angle of 30-degree or more and less than 60-degree with respect to the wiring board 102. This shaping is executed after the adhesive 201 has been applied to the edge of the part body 101a and the wiring board 102 and before the adhesive 201 hardens. Through the shaping process, the adhesive 201 can be in such a shape as to be suitable for dispersing the stress generated between the part body 101a and the wiring board 102, and thereby it is possible to further secure adhesive strength of the electronic part 101 of the BGA type that is mounted on the wiring board.

Also in the present example shown in FIG. 4, in the same way as the one shown in FIG. 2, the repair processing can be easily executed for the BGA type electronic part 101 in the mounted state.

Next, an explanation will be given about a method of mounting the BGA type electronic part 101 on the wiring board 102.

The mounting method to be described below, which corresponds to the example shown in FIG. 4, includes each step of the mounting method corresponding to the example shown in FIG. 2, and further has additional steps. Thus, description below will focus on the additional steps.

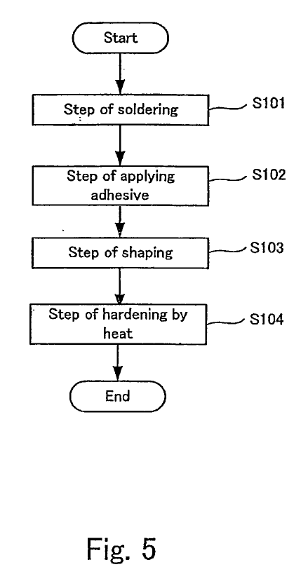

FIG. 5 is a flowchart illustrating the mounting method for mounting the BGA type electronic part 101 on the wiring board 102 in the example shown in FIG. 4. In the following explanation, reference is made without mentioning reference characters and numerals of the component elements shown in FIG. 4.

The mounting method illustrated in this flowchart of FIG. 5 corresponds to one embodiment of the mounting method of an electronic part according to the present invention.

In this mounting method, first of all, the step of soldering (step S101) is executed, which solders the BGA type electronic part 101 to the wiring board 102. This step of soldering (step S101) corresponds to an example of the connecting process according to the present invention. In the step of soldering (step S101), the BGA type electronic part 101 is placed on the wiring board 102, by placing plural bumps 101b on plural land terminals 102a so as to align the bumps 101b with the land terminals 102a. Through heating treatment after the placement, the bumps 101b are melted, so that the BGA type electronic part 101 is soldered to the wiring board 102.

Next, the step of applying adhesive (step S102) is executed, which applies the adhesive 201 to the edge of the part body 101a of the BGA type electronic part 101 and the wiring board 102. The adhesive 201 is applied to the entire perimeter of the part body 101a excepting one arbitrary portion 101a_1 to secure an escape route of the air accumulated in the space between the lower portion of the part body 101a and the wiring board 102.

After the step of applying adhesive (step S102) is finished, with the adhesive 201 yet to be hardened, the step of shaping (step S103) is executed, which shapes this adhesive 201. In this step of shaping (step S103), in order to make the shape formed by the applied adhesive 201 suitable for dispersing stress generated between the wiring board 102 and the part body 101a mounted on the wiring board, a slant surface is formed which spreads from the part body 101a to the wiring board 102 and has a slant angle of not less than 30-degree and less than 60-degree relative to the wiring board.

After the step of shaping (step S103) is finished, the step of hardening by heat (step S104) is executed, which hardens the adhesive 201 through heating. Through the step of hardening by heat (step S104), the adhesive 201 hardens and the mounting of the BGA type electronic part 101 on the wiring board 102 is finished. Here, for a time period from the step of applying adhesive (step S102) until the completion of the step of hardening by heat (step S104), the adhesive 201 maintains a viscosity of not less than 50 Pa·s. As a result, the adhesive 201 does not enter the space between the BGA type part body 101a of the electronic part 101 and the wiring board 102, due to a capillary phenomenon or the like. Therefore, it is possible to avoid unwanted spread of adhesion into a lower portion of the part body 101a. Here, the processing from the step of applying adhesive (step S102) to the step of hardening by heat (step S104) corresponds to an example of the step of bonding according to the present invention.

According to the mounting method illustrated in the flowchart explained above, it is possible to mount the BGA type electronic part 101 on the wiring board 102 in the example shown in FIG. 4, which enables easy repair processing for the BGA type electronic part 101 in the mounted state. Incidentally, the mounting method corresponding to the example shown in FIG. 2 is identical with the flowchart shown in FIG. 5 excepting the step of shaping (step S103). However, with the mounting method shown in FIG. 2, similarly to the mounting method shown in the flowchart of FIG. 5, the BGA type electronic part 101 can be mounted on the wiring board 102 in such a manner that makes the repair processing easy.

In addition, in the above description, as an example of the electronic part according to the present invention, the BGA type electronic part 101 has been cited. However, the electronic part of the present invention is not limited to this, and for example, it may be a CSP type electronic part.

Also, in the above description, as an example of the adhesive according to the present invention, the adhesives 105 and 201 are cited for bonding the edge of the part body 101a to the wiring board 102 excepting one arbitrary portion 101a_1 of the entire perimeter. However, the present invention is not limited to this, and for example, the adhesive of the present invention may be one that bonds the edge of the part body to the wiring board excepting two and more portions of the edge.

Also, in the above description, as an example of the adhesive according to the present invention, the adhesives 105 and 201 have been cited for bonding 90% or more of the entire perimeter of the edge of the part body 101a to the wiring board. However, the present invention is not limited to this, and for example, the adhesive of the present invention may be one that bonds 50% or less of the part body to the wiring board, as far as the bonded area includes at least the corners of the part body.

Also, in the above description, as an example of the adhesive according to the present invention, the thermosetting adhesives 105 and 201 have been cited. However, the present invention is not limited to this, and for example, the adhesive of the present invention may be a thermoplastic adhesive or the like.

What is claimed is:

1. An electronic apparatus comprising:
a package body that has a tabular outside shape and is packaged with a built-in electronic circuit;
a bump that electrically connects the electronic circuit inside the package body to a wiring outside the package body;
a wiring board that has a wiring at least on its surface, the wiring board mounted with the package body so that the electronic circuit of the package body is electrically connected to the wiring via the bump; and
an adhesive that bonds the package body to the wiring board so as to bond only an edge of the package body to the wiring board.

2. The electronic apparatus according to claim 1, wherein the adhesive bonds the edge of the package body to the wiring board excepting a portion of the perimeter of the edge.

3. The electronic apparatus according to claim 1, wherein the package body has a rectangular outside shape, and the adhesive bonds at least corners of the rectangular outside shape of the edge of the package body, to the wiring board.

4. The electronic apparatus according to claim 1, wherein the adhesive widens from the package body toward the wiring board.

5. The electronic apparatus according to claim 1, wherein the adhesive, which widens from the package body to the wiring board, has a slant surface with a slant angle of not less than 30-degree and less than 60-degree with respect to the wiring board.

6. The electronic apparatus according to claim 1, wherein the adhesive has a viscosity of not less than 50 Pa·s before hardening.

7. The electronic apparatus according to claim 1, wherein the adhesive is kept from contact with the bump.

8. A mounting method comprising the steps of:
electrically connecting an electronic circuit embedded and packaged inside a package body to a wiring of a wiring board via a bump that electrically connects the electronic circuit to a wiring outside the package body, the package body having a tabular outside shape, the wiring being laid at least on a surface of the wiring board; and
bonding the package body to the wiring board so as to bond only an edge of the package body to the wiring board.

9. The mounting method according to claim 8, wherein the step of bonding is a step of bonding the edge of the package body to the wiring board excepting a portion of the perimeter of the edge.

10. The mounting method according to claim 8, wherein the package body has a rectangular outside shape, and the step of bonding is a step of bonding at least corners of the rectangular outside shape of the edge of the package body, to the wiring board.

11. The mounting method according to claim 8, wherein the step of bonding is a step that executes the bonding with the use of an adhesive, and further that spreads the adhesive from the package body toward the wiring board.

12. The mounting method according to claim 8, wherein the step of bonding is a step that executes the bonding with the use of an adhesive, and further that spreads the adhesive from the package body to the wiring board so that the adhesive has a slant surface with a slant angle of not less than 30-degree and less than 60-degree with respect to the wiring board.

13. The mounting method according to claim 8, wherein the step of bonding is a step that executes the bonding with the use of an adhesive having a viscosity of not less than 50 Pa·s before hardening.

14. The mounting method according to claim 8, wherein the step of bonding is a step that executes the bonding with the use of an adhesive, and further that executes the bonding in such a way that the adhesive is kept from contact with the bump.
